(19) United States
(12) Patent Application Publication
(10) Pub. No.: US 2026/0313787 A1
(43) Pub. Date: Oct. 8, 2026

(54) PRINTED CIRCUIT BOARD

(71) Applicant: SAMSUNG ELECTRO-MECHANICS CO., LTD., Suwon-si (KR)

(72) Inventor: In Gun KIM, Suwon-si (KR)

(73) Assignee: SAMSUNG ELECTRO-MECHANICS CO., LTD., Suwon-si (KR)

(21) Appl. No.: 19/716,526

(22) Filed: Jun. 23, 2026

Related U.S. Application Data
(63) Continuation of application No. 18/443,553, filed on Feb. 16, 2024.

(30) Foreign Application Priority Data
Aug. 25, 2023 (KR) 10-2023-0112008

(51) Int. Cl. H05K 1/02; H05K 1/11

(52) U.S. Cl. CPC H05K 1/0271; H05K 1/0256; H05K 1/116; H05K 2201/0338; H05K 2201/0355; H05K 2201/094; H05K 2201/09518

(57) ABSTRACT

A printed circuit board includes a glass layer having a first surface, and a second surface opposing the first surface, a through-via penetrating the glass layer, a first wiring layer disposed on and in contact with the first surface of the glass layer, a first insulating layer disposed on the first surface and covering the first wiring layer, a second insulating layer disposed on the second surface of the glass layer and covering a side surface of the glass layer connecting the first and second surfaces of the glass layer, a second wiring layer disposed on the second insulating layer, and a connection via penetrating the second insulating layer to connect the second wiring layer and the through-via to each other, the connection via being in contact with the through-via. The first insulating layer includes an insulating material different from an insulating material of the second insulating layer.

### CROSS-REFERENCE TO RELATED APPLICATION(S)

This application is the continuation application of U.S. Patent Application No. 18/443,553 filed on Feb. 16, 2024, which claims the benefit of priority to Korean Patent Application No. 10-2023-0112008, filed on Aug. 25, 2023 in the Korean Intellectual Property Office, the disclosure of which is incorporated herein by reference in its entirety.

### TECHNICAL FIELD

The present disclosure relates to a printed circuit board.

### BACKGROUND

Multichip packages including a memory chip such as a high bandwidth memory (HBM) and a processor chip such as a central processing unit (CPU), a graphics processing unit (GPU), an application specific integrated circuit (ASIC), or a field programmable gate array (FPGA) have been used to process data exponentially increasing due to recent developments in artificial intelligence (AI) technology. Accordingly, demand for a large-area board has been increasing. An issue, such as warpage, may be overcome using a glass material, even when a large-area board is manufactured. Thus, attempts have been made to use glass materials.

### SUMMARY

An aspect of the present disclosure provides a printed circuit board including a glass layer.

Another aspect of the present disclosure provides a printed circuit board having improved warpage properties.

Another aspect of the present disclosure provides a printed circuit board having improved reliability.

According to an aspect of the present disclosure, there is provided a printed circuit board including a glass layer having a first surface, and a second surface opposing the first surface, a through-via penetrating the glass layer, a first wiring layer disposed on and in contact with the first surface of the glass layer, a first insulating layer disposed on the first surface and covering the first wiring layer, a second insulating layer disposed on the second surface of the glass layer and covering a side surface of the glass layer connecting the first and second surfaces of the glass layer, a second wiring layer disposed on the second insulating layer, and a connection via penetrating the second insulating layer to connect the second wiring layer and the through-via to each other, the connection via being in contact with the through-via. The first insulating layer may include an insulating material different from an insulating material of the second insulating layer.

According to another aspect of the present disclosure, there is provided a printed circuit board including a glass layer having a first surface, and a second surface opposing the first surface, a through-via penetrating the glass layer, a first wiring layer disposed on the first surface of the glass layer, the first wiring layer having an interface with the through-via, the first wiring layer including a first metal layer and a second metal layer disposed on the first metal layer, a first insulating layer disposed on the first surface and covering the first wiring layer, a second insulating layer disposed on the second surface of the glass layer and covering a side surface of the glass layer connecting the first and second surfaces of the glass layer, the second insulating layer being in contact with a portion of the first insulating layer, a second wiring layer disposed on the second insulating layer, and a connection via penetrating the second insulating layer to connect the second wiring layer and the through-via to each other. At least a portion of the first metal layer may be in contact with the through-via and extend onto the first surface.

According to example embodiments of the present disclosure, there may be provided a printed circuit board including a glass layer.

According to example embodiments of the present disclosure, there may be provided a printed circuit board having improved warpage properties.

According to example embodiments of the present disclosure, there may be provided a printed circuit board having improved reliability.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view illustrating an example of a printed circuit board;

FIG. 4 is a schematic cross-sectional view illustrating another example of a printed circuit board;

FIG. 5 is a schematic cross-sectional view illustrating still another example of a printed circuit board; and

FIGS. 6, 7, 8, 9, 10, 11, 12, 13, 14, 15 and 16 are schematic cross-sectional views illustrating an example of a method of manufacturing a printed circuit board.

### DETAILED DESCRIPTION

Hereinafter, the present disclosure will be described with reference to the accompanying drawings. The shapes and sizes of components in the drawings may be exaggerated or reduced for clearer description.

### Electronic Device

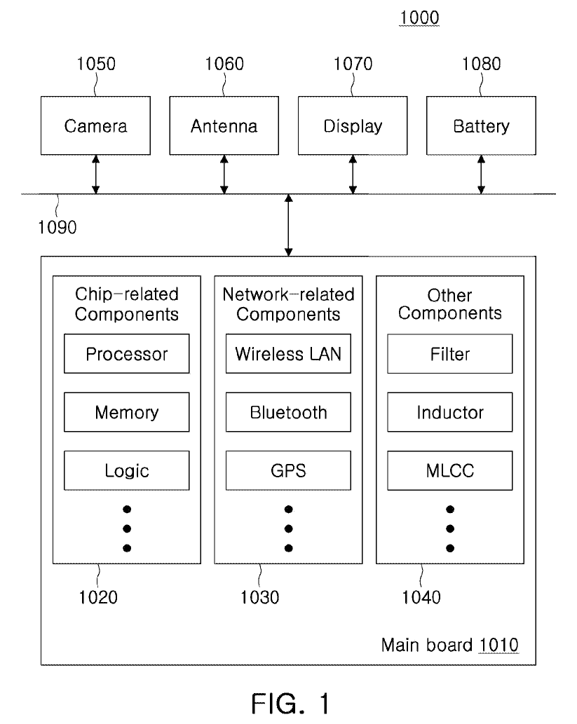

FIG. 1 is a schematic block diagram illustrating an example of an electronic device system.

Referring to FIG. 1, an electronic device 1000 may accommodate a mainboard 1010. The mainboard 1010 may include chip-related components 1020, network-related components 1030, and other components 1040, physically or electrically connected thereto. Such components may be connected to other components to be described below to form various signal lines 1090.

The chip-related components 1020 may include a memory chip such as a volatile memory (for example, a dynamic random access memory (DRAM)), a non-volatile memory (for example, a read only memory (ROM)), or a flash memory, an application processor chip such as a central processor (for example, a central processing unit (CPU)), a graphics processor (for example, a graphics processing unit (GPU)), a digital signal processor, a cryptographic processor, a microprocessor, or a microcontroller, and a logic chip such as an m analog-to-digital converter or an application-specific integrated circuit (ASIC). However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family or the like), worldwide interoperability for microwave access (WiMAX) (IEEE 802.16 family or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

The other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, the other components 1040 are not limited thereto, and may also include passive components used for various other purposes, or the like. In addition, the other components 1040 may be combined with each other, together with the chip-related components 1020 or the network-related components 1030 described above.

Depending on a type of the electronic device 1000, the electronic device 1000 may include other components that may be or may not be physically or electrically connected to the mainboard 1010. The other components may include, for example, a camera module 1050, an antenna module 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on the type of electronic device 1000.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

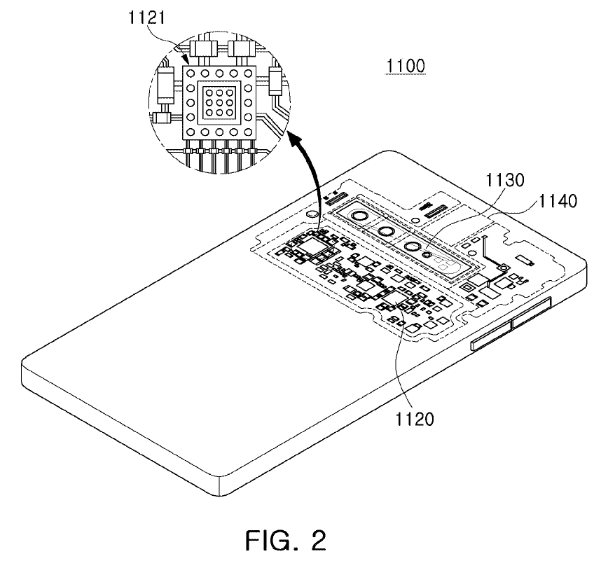

FIG. 2 is a schematic perspective view illustrating an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may be or may not be physically and/or electrically connected to the motherboard 1110 may be accommodated therein, such as a camera module 1130 and/or a speaker 1140. A portion of the electronic components 1120 may be the chip-related components described above, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices as described above.

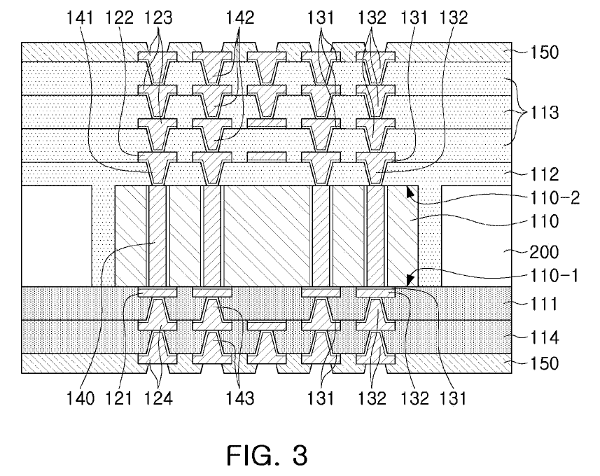

FIG. 3 is a schematic cross-sectional view illustrating an example of a printed circuit board.

Referring to FIG. 3, a printed circuit board according to an example may include a glass layer 110 having a first surface 110-1 and a second surface 110-2 opposing the first surface 110-1, a through-via 140 penetrating the glass layer 110, a first wiring layer 121 disposed on the first surface 110-1 of the glass layer 110, a first insulating layer 111 disposed on the first surface 110-1 of the glass layer 110 to be in contact with the first surface 110-1, the first insulating layer 111 covering the first wiring layer 121, a second insulating layer 112 disposed on the second surface 110-2 of the glass layer 110, the second insulating layer 112 covering a side surface of the glass layer 110 connecting the first surface 110-1 and the second surface 110-2 of the glass layer 110, a second wiring layer 122 disposed on the second insulating layer 112, and a connection via 141 penetrating the second insulating layer 112 to connect the second wiring layer 122 and the through-via 140 to each other, the connection via 141 in contact with the through-via 140.

The printed circuit board according to an example including the glass layer 100 may basically have excellent flatness and may also have a low coefficient of thermal expansion (CTE), which may be advantageous in warpage control. In particular, the printed circuit board according to an example may include the glass layer 100 as a core, and thus may be advantageous in warpage control even in an operation of stacking other insulating layers. In addition, the first insulating layer 111 may be formed on the first surface 110-1 of the glass layer 110, and the second insulating layer 112 may be formed on the second surface 110-2 of the glass layer 110, and thus the flatness may be further improved. Accordingly, it may be more advantageous in forming a high-density fine circuit having a fine pitch. In addition, the properties of glass having variable properties of Dk 2.5 to 11 may reduce the number of layers of the printed circuit board and further increase a degree of design freedom.

The printed circuit board according to an example may include the first insulating layer 111, stacked on the first surface 110-1 of the glass layer 110, and the second insulating layer 112, stacked on the second surface 110-2 of the glass layer 110, including different materials. Even when insulating layers of the printed circuit board are stacked on each other such that the first insulating layer 111 and the second insulating layer 112 include different insulating materials, stiffness may be secured through the glass layer 110, thereby protecting the printed circuit board from warpage. However, the present disclosure is not limited thereto, and the printed circuit board may be protected from warpage, even when insulating layers respectively stacked on the first insulating layer 111 and the second insulating layer 112 include different materials or the number of insulating layers stacked on the first insulating layer 111 is different from the number of insulating layers stacked on the second insulating layer 112.

The glass layer 110 may include glass, an amorphous solid. Glass may include, for example, pure silicon dioxide (about 100% SiO₂), soda lime glass, borosilicate glass, alumino-silicate glass, and the like. However, the present disclosure is not limited thereto, and an alternative glass material such as fluorine glass, phosphate glass, chalcogen glass, or the like may also be used as a material for the glass layer 100. In addition, other additives may be further included to form glass with specific physical properties. Such additives may include calcium carbonate (for example, lime) and sodium carbonate (for example, soda), as well as magnesium, calcium, manganese, aluminum, lead, boron, iron, chromium, potassium, sulfur and antimony, and a carbonate and/or an oxide of such elements and other elements. The glass layer 110, a layer distinguished from a material including a glass fiber (or glass cloth or glass fabric), for example, a copper clad laminate (CCL), a prepreg (PPG), or the like, may be understood as, for example, plate glass.

The glass layer 110 may have the first surface 110-1 and the second surface 110-2. The second surface 110-2 may be a surface opposing the first surface 110-1. The first surface 110-1 and the second surface 110-2 may be positioned to oppose each other with respect to a stacking direction of the printed circuit board. In FIG. 3, for ease, the first surface 110-1 is illustrated as a lower side of the glass layer 110, and the second surface 110-2, opposing the first surface 110-1, is illustrated as an upper side of the glass layer 110. However, positions of the first surface 110-1 and the second surface 110-2 are illustrated for ease, and are not limited thereto. A positional relationship between the first surface 110-1 and the second surface 110-2 may vary.

Referring to FIG. 3, in the printed circuit board according to an example, the first wiring layer 121 may be disposed on the first surface 110-1 of the glass layer 110 to be in contact with the first surface 110-1, and the first wiring layer 121 may be connected to the through-via 140 to be in contact with the through-via 140. The second wiring layer 122 may be disposed on the second insulating layer 112, and may be connected to the through-via 140 through the connection via 141. The connection via 141 may penetrate the second insulating layer 112, and may be connected to the through-via 140 to be in contact with the through-via 140. That is, the through-via 140 of the glass layer 110 may be in contact with the first wiring layer 121 on the first surface 110-1 side, and may be in contact with the connection via 141 on the second surface 110-2. That is, the printed circuit board according to an example may be implemented as an asymmetrical board including different components in contact with the first surface 110-1 and the second surface 110-2 of the glass layer 110, respectively.

The first insulating layer 111 and the second insulating layer 112 may include an organic insulating material. The organic insulating material may include a thermosetting resin such as an epoxy resin, a thermoplastic resin such as polyimide, or a material including an inorganic filler, an organic filler, and/or a glass fiber (or glass cloth or glass fabric), together with such resins. For example, the insulating material may be a non-photosensitive insulating material such as an Ajinomoto build-up film (ABF) or PPG, but the present disclosure is not limited thereto, and other polymer materials may be used. In addition, the insulating material may be a photosensitive insulating material such as a photo-imageable dielectric (PID). In addition, the insulating material may include an adhesive sheet such as a bonding sheet (BS).

The first insulating layer 111 and the second insulating layer 112 may include different insulating materials. The different insulating materials may mean not only different types of insulating materials in the above-described insulating material group, but also the same type of insulating materials respectively including partially different types of compositions. For example, the first insulating layer 111 and the second insulating layer 112 may respectively include an ABF, but a composition contained in the first insulating layer 111 and a composition contained in the second insulating layer 112 may be partially different from each other.

That is, the first insulating layer 111 and the second insulating layer 112 may respectively include a filler, but respective fillers may be different from each other, such that the first insulating layer 111 and the second insulating layer 112 may include different insulating materials. The filler included in the second insulating layer 112 may have a structure finer than that of the filler included in the first insulating layer 111. In this case, the filler may be an inorganic filler, but the present disclosure is not necessarily limited thereto. The filler included in the second insulating layer 112 finer than the filler included in the first insulating layer 111 may mean that a size, such as a diameter or volume, of the filler included in the second insulating layer 112 is smaller than a size, such as a diameter or volume, of the filler included in the first insulating layer 111.

The fillers included in the first insulating layer 111 and the second insulating layer 112, different from each other, may be identified by analyzing a vertical cross-sectional view of the printed circuit board. The fillers may be compared to each other using a scanning microscope or optical microscope with respect to a polished or cut cross-section of the printed circuit board. If necessary, the fillers may be more easily identified by staining a vertical cross-section of the printed circuit board. As described above, the diameters of the fillers may be measured using a scanning microscope or optical microscope with respect to the polished or cut cross-section of the printed circuit board. Average values of the diameters may be compared to each other. Here, the average value of the diameter may be an average of values measured at any five points.

The printed circuit board according to an example may include a core 200. The core 200 may include a material different from those of the first and second insulating layers 111 and 112. For example, the core 200 may include a material having stiffness greater than those of the first and second insulating layers 111 and 112, and may include an insulating material such as a copper clad laminate (CCL). The core 200 may be used as a jig, supporting the glass layer 110, to perform a process of embedding the glass layer 110, thereby preventing the glass layer 110 from being damaged during a process of manufacturing the printed circuit board. The core 200 may also be disposed on an outermost side of the printed circuit board to protect the printed circuit board.

The glass layer 110 may be disposed in a through-hole formed in the core 200, and may be buried by the second insulating layer 112. That is, the second insulating layer 112 may be disposed on the second surface 110-2 of the glass layer 110, and may be disposed to cover the side surface of the glass layer 110. In this case, the second insulating layer 112 may also be disposed on the core 200, and may be disposed to fill the through-hole formed in the core 200. In addition, a lower surface of the core 200 may be substantially coplanar with the first surface 110-1 of the glass layer 110. This may be because the glass layer 110 is fixed in the through-hole of the core 200 and then buried by the second insulating layer 112. An arrangement relationship between the core 200, the glass layer 110, the first insulating layer 111, and the second insulating layer 112 will be described in detail below in connection with a method of manufacturing the printed circuit board.

The first wiring layer 121 and the second wiring layer 122 may respectively include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The first wiring layer 121 and the second wiring layer 122 may perform various functions depending on the design. For example, the first wiring layer 121 and the second wiring layer 122 may include a signal pattern, a power pattern, a ground pattern, and the like. The patterns may have various forms such as lines, planes, and pads. The first wiring layer 121 and the second wiring layer 122 may include an electroless plating layer (or chemical copper) and an electrolytic plating layer (or electrical copper). Alternatively, the first wiring layer 121 and the second wiring layer 122 may include a metal foil (or copper foil) and an electrolytic plating layer (or electrolytic copper). Alternatively, the first wiring layer 121 and the second wiring layer 122 may include a metal foil (or copper foil), an electroless plating layer (or chemical copper), and an electrolytic plating layer (or electrolytic copper). The first wiring layer 121 and the second wiring layer 122 may include a sputtering layer instead of the electroless plating layer (or chemical copper), and may include both the sputtering layer and the electroless plating layer (or chemical copper), as necessary.

Each of the first wiring layer 121 and the second wiring layer 122 may be formed using one of a semi additive process (SAP), a modified semi additive process (MSAP), tenting (TT), or subtractive method, but the present disclosure is not limited thereto. Any method capable of forming a circuit on a printed circuit board may be used without limitation. In addition, the first wiring layer 121 and the second wiring layer 122 may be formed using different methods depending on the purpose and design.

The first wiring layer 121 may include a first metal layer 131 and a second metal layer 132, and the second wiring layer 122 may also include a first metal layer 131 and a second metal layer 132. Each of the first metal layer 131 and the second metal layer 132 may form the first wiring layer 121 and the second wiring layer 122, and the first metal layer 131 and the second metal layer 132 may include the same metal. The first metal layer 131 may function as a seed for forming the second metal layer 132. The first metal layer 131 may include electroless plating (or chemical copper), and may include a sputtering layer. Alternatively, the first metal layer 131 may include metal foil (or copper foil). The first metal layer 131 of the second wiring layer 122, disposed on the second insulating layer 112, may preferably include an electroless plating layer, but the present disclosure is not limited thereto. The first metal layer 131 of the first wiring layer 121, disposed on the glass layer 110, may preferably include a sputtering layer. When the first metal layer 131 of the first wiring layer 121 includes a sputtering layer, it may be advantageous to secure adhesion between the glass layer 110 and the first metal layer 131. However, the present disclosure is not necessarily limited thereto, and the first metal layer 131 of the first wiring layer 121 may include an electroless plating layer. In order to secure adhesion between the glass layer 110 and the first wiring layer 121, other components may also be included. The second metal layer 132 may include an electrolytic plating layer formed using the first metal layer 131 as a seed.

The through-via 140 may include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The through-via 140 may penetrate the first surface 110-1 and the second surface 110-2 of the glass layer 100. Upper and lower surfaces of the through-via 140 may be substantially coplanar with the first surface 110-1 and the second surface 110-2 of the glass layer 100. The through-via 140 may be a filled via being filled with a metal layer, but the present disclosure is not limited thereto. The through-via 140 may be a conformal via, disposed along a wall surface of a via hole, and a specific method of forming the through-via 140 may vary. The through-via 140 may perform various functions depending on the design. For example, the through-via 140 may include a ground via, a power via, a signal via, and the like. The through-via 140 may have a substantially circular shape, an elliptical shape, or a polygonal shape on a plane, but the present disclosure not limited thereto, and may have, for example, a complex shape in which various shapes are combined into one on a plane in terms of securing close contact by increasing a specific surface area. A side surface of the through-via 140 may be substantially perpendicular to the upper and lower surfaces of the through-via 140, but the present disclosure is not limited thereto, and may be tapered to have an hourglass shape in cross-section, as necessary.

The connection via 141 may include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The connection via 141 may include a filled via filling a via hole, but may also include a conformal via disposed along a wall surface of the via hole. The connection via 141 may perform various functions depending on the design. For example, the connection via 141 may include a ground via, a power via, a signal via, and the like. The connection via 141 may include a first metal layer 131 and a second metal layer 132 in the same manner as the second wiring layer 122.

The connection via 141 may penetrate the second insulating layer 112 to connect the second wiring layer 122 and the through-via 140 to each other. The connection via 141 may be directly connected to the upper surface of the through-via 140. That is, a lower surface of the connection via 141 and the upper surface of the through-via 140 may be connected to each other on the second surface 110-2 of the glass layer 110. Adhesion between the glass layer 110 and a metal material may not be easily secured. Thus, after the second insulating layer 112 is formed on the second surface 110-2 of the glass layer 110, the through-via 140 and the second wiring layer 122 may be connected to each other by forming a via hole penetrating the second insulating layer 112 and forming the connection via 141 filling the via hole. In this case, the connection via 141 may be formed to fill the via hole of the second insulating layer 112 and may be formed simultaneously with the second wiring layer 122. That is, the first metal layer 131, a seed layer of the connection via 141, may be disposed on the through-via 140, and may cover at least a portion of the through-via 140. When a bottom surface of a via hole for the connection via 141 is wider than the upper surface of the through-via 140, the connection via 141 may be formed to entirely cover the through-via 140. When the bottom surface of the via hole is narrower than the upper surface of the through-via 140, the connection via 141 may be formed to cover a portion of the through-via 140.

The printed circuit board according to an example may include one or more third insulating layers 113 disposed on the second insulating layer 112, the one or more third insulating layers 113 covering at least a portion of the second wiring layer 122, and one or more the third wiring layers 123 respectively disposed on or within the third insulating layers 113, and may include one or more first via layers 142 penetrating at least a portion of the third insulating layers 113 to connect the third wiring layers 123 and the second wiring layer 122 to each other. In addition, the printed circuit board according to an example may include one or more fourth insulating layers 114 disposed on the first insulating layer 111, the one or more fourth insulating layers 114 covering at least a portion of the first wiring layer 121, and one or more fourth wiring layers 124 respectively disposed on or within the fourth insulating layers 114, and may include one or more second via layers 143 penetrating at least a portion of the fourth insulating layers 114 to connect the fourth wiring layers 124 and the first wiring layer 121 to each other.

The one or more third insulating layers 113 may respectively include an organic insulating material. The organic insulating material may include a thermosetting resin such as an epoxy resin, a thermoplastic resin such as polyimide, or a material including an inorganic filler, an organic filler, and/or a glass fiber (or glass cloth or glass fabric), together with such resins. For example, the insulating material may be a non-photosensitive insulating material such as an ABF or PPG, but the present disclosure is not limited thereto, and other polymer materials may be used. In addition, the insulating material may be a photosensitive insulating material such as a PID. In addition, the insulating material may include an adhesive sheet such as a BS. The third insulating layers 113 may include an insulating material substantially the same as that of the second insulating layer 112, but the present disclosure is not limited thereto, and may include different insulating materials. When the third insulating layers 113 includes an insulating material substantially the same as that of the second insulating layer 112, the third insulating layers 113 may include an insulating material different from that of the first insulating layer 111. The glass layer 110 may secure stiffness, and thus, even when the second insulating layer 112 and the third insulating layers 113 include an insulating material different from that of the first insulating layer 111, warpage of the printed circuit board may be prevented.

The one or more third wiring layers 123 may respectively include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The third wiring layers 123 may perform various functions depending on the design. For example, the third wiring layers 123 may include a signal pattern, a power pattern, a ground pattern, and the like. The patterns may have various forms such as lines, planes, and pads. The third wiring layers 123 may include an electroless plating layer (or chemical copper) and an electrolytic plating layer (or electrical copper). Alternatively, the third wiring layers 123 may include a metal foil (or copper foil) and an electrolytic plating layer (or electrolytic copper). Alternatively, the third wiring layers 123 may include a metal foil (or copper foil), an electroless plating layer (or chemical copper), and an electrolytic plating layer (or electrolytic copper). The third wiring layers 123 may include a sputtering layer instead of the electroless plating layer (or chemical copper), and may include both the sputtering layer and the electroless plating layer (or chemical copper), as necessary.

The one or more first via layers 142 may respectively include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The first via layers 142 may include a filled via filling a via hole, but may also include a conformal via disposed along a wall surface of the via hole. The first via layers 142 may perform various functions depending on the design. For example, the first via layers 142 may include a ground via, a power via, a signal via, and the like. The first via layers 142 may include an electroless plating layer (or chemical copper) and an electrolytic plating layer (or electrical copper). The first via layers 142 may include a sputtering layer instead of the electroless plating layer (or chemical copper), and may include both the sputtering layer and the electroless plating layer (or chemical copper), as necessary.

Each of the third wiring layers 123 and the first via layers 142 may be formed using one of an SAP, an MSAP, TT, or subtractive method, but the present disclosure is not limited thereto. Any method capable of forming a circuit on a printed circuit board may be used without limitation.

The one or more fourth insulating layers 114 may respectively include an organic insulating material. The organic insulating material may include a thermosetting resin such as an epoxy resin, a thermoplastic resin such as polyimide, or a material including an inorganic filler, an organic filler, and/or a glass fiber (or glass cloth or glass fabric), together with such resins. For example, the insulating material may be a non-photosensitive insulating material such as an ABF or PPG, but the present disclosure is not limited thereto, and other polymer materials may be used. In addition, the insulating material may be a photosensitive insulating material such as a PID. In addition, the insulating material may include an adhesive sheet such as a BS. The fourth insulating layers 114 may include an insulating material substantially the same as that of the first insulating layer 111, but the present disclosure is not limited thereto, and may include different insulating materials. When the fourth insulating layers 114 includes an insulating material substantially the same as that of the first insulating layer 111, the fourth insulating layers 114 may include an insulating material different from that of the second insulating layer 112. The glass layer 110 may secure stiffness, and thus, even when the first insulating layer 111 and the fourth insulating layers 114 include an insulating material different from that of the second insulating layer 112, warpage of the printed circuit board may be prevented.

The one or more fourth wiring layers 124 may respectively include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The fourth wiring layers 124 may perform various functions depending on the design. For example, the fourth wiring layers 124 may include a signal pattern, a power pattern, a ground pattern, and the like. The patterns may have various forms such as lines, planes, and pads. The fourth wiring layers 124 may include an electroless plating layer (or chemical copper) and an electrolytic plating layer (or electrical copper). Alternatively, the fourth wiring layers 124 may include a metal foil (or copper foil) and an electrolytic plating layer (or electrolytic copper). Alternatively, the fourth wiring layers 124 may include a metal foil (or copper foil), an electroless plating layer (or chemical copper), and an electrolytic plating layer (or electrolytic copper). The fourth wiring layers 124 may include a sputtering layer instead of the electroless plating layer (or chemical copper), and may include both the sputtering layer and the electroless plating layer (or chemical copper), as necessary.

The one or more second via layers 143 may respectively include metal. The metal may include copper (Cu), aluminum (Al), silver (Ag), tin (Sn), gold (Au), nickel (Ni), lead (Pb), titanium (Ti), and/or alloys thereof. Preferably, the metal may include copper (Cu), but the present disclosure is not limited thereto. The second via layers 143 may include a filled via filling a via hole, but may also include a conformal via disposed along a wall surface of the via hole. The second via layers 143 may perform various functions depending on the design. For example, the second via layers 143 may include a ground via, a power via, a signal via, and the like. The second via layers 143 may include an electroless plating layer (or chemical copper) and an electrolytic plating layer (or electrical copper). The second via layers 143 may include a sputtering layer instead of the electroless plating layer (or chemical copper), and may include both the sputtering layer and the electroless plating layer (or chemical copper), as necessary.

Each of the fourth wiring layers 124 and the second via layers 143 may be formed using one of an SAP, an MSAP, TT, or subtractive method, but the present disclosure is not limited thereto. Any method capable of forming a circuit on a printed circuit board may be used without limitation.

As described above, the third insulating layers 113 may include an insulating material substantially the same as that of the second insulating layer 112, and the fourth insulating layers 114 may include an insulating material substantially the same as that of the first insulating layer 111. The substantially the same insulating material may mean not only completely the same insulating material, but also the same type of insulating material. Accordingly, the third insulating layers 113 and the fourth insulating layers 114 may respectively include a filler, and sizes of the fillers of the third insulating layers 113 and the fourth insulating layers 114 may be substantially the same as those of the fillers included in the second insulating layer 112 and the first insulating layer 111, respectively.

The second insulating layer 112 and the third insulating layers 113 may be disposed on the second surface 110-2 of the glass layer 110, the first insulating layer 111 and the fourth insulating layers 114 may be disposed on the first surface 110-1 of the glass layer 110, and an insulating layer disposed on the second surface 110-2 and an insulating layer disposed on the first surface 110-1 may include different insulating materials. The insulating layer disposed on the second surface 110-2 may include a filler finer than a filler included in the insulating layer disposed on the first surface 110-1. A method of comparing diameters of the fillers may be performed in the same manner as the method of comparing the diameters of the fillers of the first and second insulating layers 111 and 112. An insulating layer including a finer filler may be advantageous in processing a finer interconnection, and thus processing a fine interconnection on the second insulating layer 112 and the third insulating layers 113 may be more advantageous than processing a fine interconnection on the first insulating layer 111 and the fourth insulating layers 114.

The number of the third insulating layers 113 and the number of the fourth insulating layers 114 may be different from each other. As illustrated in FIG. 3, the number of the third insulating layers 113 may be greater than the number of the fourth insulating layers 114, but the present disclosure is not necessarily limited thereto. That is, the number of the third insulating layers 113 and the number of the fourth insulating layers 114 may be different from each other, and thus the printed circuit board according to an example may have an asymmetric structure. In general, a board having an asymmetric structure may be vulnerable to warpage due to different numbers of stacks and processes. However, the printed circuit board according to an example may include a glass layer 110 having high stiffness, thereby preventing warpage. In FIG. 3, the third insulating layers 113 are illustrated as three insulating layers, and the fourth insulating layers 114 are illustrated as one insulating layer, but the number of layers is not limited thereto. The number of the third wiring layers 123, a portion connected to other components such as semiconductor chips, may be greater than the number of the fourth wiring layers 124, disposed on an opposite side. The portion connected to other components such as semiconductor chips may require a greater number of wiring layers. However, it may be common to implement wiring layers to be symmetrical to each other to prevent warpage. Conversely, the printed circuit board according to an example may prevent warpage using the glass layer 110, and thus the number of the third wiring layers 123 and the number of the third insulating layers 113 may be greater than the number of the fourth wiring layers 124 and the number of the fourth insulating layers 114.

The printed circuit board according to an example may have different layer configurations with respect to the glass layer 110, as described above. That is, insulating layers stacked on the first surface 110-1 and the second surface 110-2 of the glass layer 110 may include different materials and have different numbers of layers. In addition, the first wiring layer 121 may be directly formed on the first surface 110-1 of the glass layer 110, the second insulating layer 112 may be formed on the second surface 110-2 of the glass layer 110, and then the second wiring layer 122 may be disposed. The through-via 140 may be in contact with the first wiring layer 121 in a direction of the first surface 110-1, and may be in contact with the connection via 141, rather than the second wiring layer 122, in a direction of the second surface 110-2.

That is, the printed circuit board according to an example may have an asymmetric structure with respect to the glass layer 110. Even when the printed circuit board has an asymmetric structure, warpage may be prevented. The first surface 110-1 and the second surface 110-2 of the glass layer 110 are not necessarily limited to those illustrated in FIG. 3, and a positional relationship between the first surface 110-1 and the second surface 110-2 may be reversed with respect to each other. For example, unlike that illustrated in FIG. 3, an insulating layer, covering a wiring layer directly formed on the glass layer 110, may include a finer filler.

The printed circuit board according to an example may further include a solder resist layer 150, disposed on the third insulating layers 113 and/or the fourth insulating layers 114. The solder resist layer 150 may be disposed on an outermost side of the printed circuit board to externally protect the printed circuit board. The solder resist layer 150 may use a known solder resist. The solder resist layer 150 may include a liquid or film-type solder resist, but the present disclosure is not limited thereto. Other types of insulating materials may be used, and a thermosetting resin and an inorganic filler dispersed in the thermosetting resin may be included, but a glass fiber may not be included. The insulating resin may be a photosensitive insulating resin, and the filler may be an inorganic filler and/or an organic filler, but the present disclosure is not limited thereto. Other polymer materials may be used, as necessary. The solder resist layer 150 may have an opening, and at least a portion of the third wiring layers 123 and the fourth wiring layers 124 may be exposed via the opening. The third wiring layers 123 and the fourth wiring layers 124, exposed via the opening, may be connected to a main board or another printed circuit board. A wiring layer, exposed via the opening, may function as a pad, and a surface treatment layer may be further formed on the pad, as necessary. Alternatively, a metal bump or post may be further formed on the pad, or the pad may protrude in the form of a pillar, as necessary.

The printed circuit board according to an example is not limited to the components illustrated in FIG. 3, and may further include a general component of a printed circuit board. That is, the printed circuit board may further include a component that could be used by those skilled in the art.

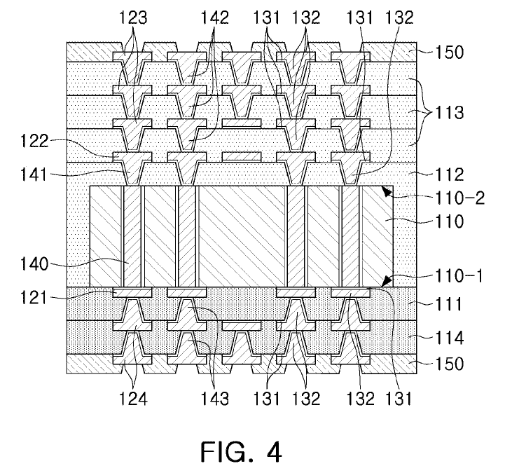

FIG. 4 is a schematic cross-sectional view illustrating another example of a printed circuit board.

Referring to FIG. 4, a printed circuit board according to another example may not include a core 200. Such a configuration may be a result of completing the printed circuit board by cutting the printed circuit board along a certain boundary after forming components of the printed circuit board in an operation of manufacturing the printed circuit board according to another example. That is, the core 200 may be a temporary component, accommodating a glass layer 110 as a jig or frame, and may be a result of forming each printed circuit board in strip units, and then manufacturing a printed circuit board through a singulation process. Accordingly, the printed circuit board according to another example may have a structure in which a second insulating layer 112, covering a side surface of the glass layer 110, is externally exposed.

Descriptions of the printed circuit board according to another example of FIG. 4, other than descriptions of the presence or absence of the core 200, may be applied in the same manner as descriptions of the printed circuit board according to an example, and thus repeated descriptions will be omitted.

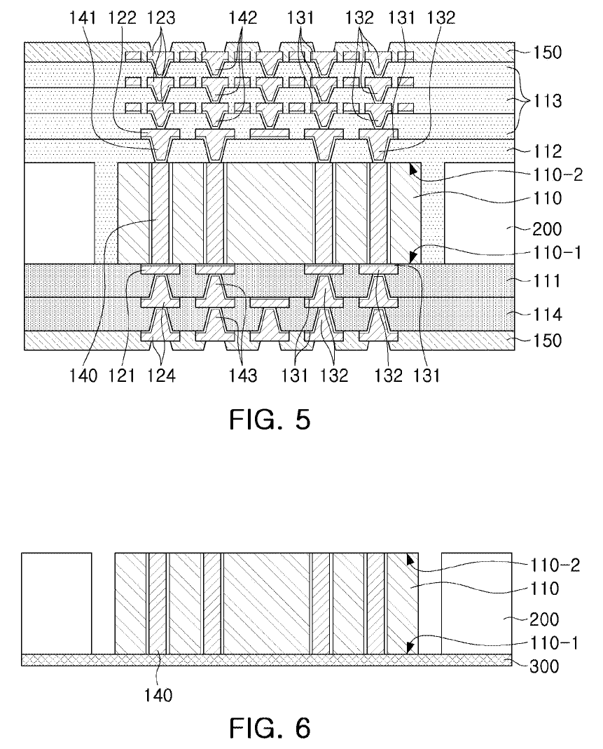

FIG. 5 is a schematic cross-sectional view illustrating still another example of a printed circuit board.

Referring to FIG. 5, in a printed circuit board according to still another example, an interconnection density of a third wiring layer 123 may be higher than an interconnection density of a first wiring layer 121 and/or an interconnection density of a fourth wiring layer 124, and a thickness of a third insulating layer 113 may be less than a thickness of a first insulating layer 111 and/or a thickness of a fourth insulating layer 114.

The third insulating layer 113 of the printed circuit board according to still another example may include a filler finer than an inorganic filler of the first insulating layer 111 and/or an inorganic filler of the fourth insulating layer 114. Accordingly, the third insulating layer 113 may be more advantageous for fine pattern processing than the first insulating layer 111 and/or the fourth insulating layer 114, such that the third wiring layer 123 disposed on or within the third insulating layer 113 may include an interconnection finer than an interconnection of the first wiring layer 121 and/or an interconnection of the fourth wiring layer 124.

Higher interconnection density may be based on a relative concept, and may mean, for example, that an average pitch of an interconnection included in the third wiring layer 123 may be shorter than an average pitch of an interconnection included in the first wiring layer 121. A pitch may be measured by photographing a cut cross-section of the printed circuit board using a scanning microscope, and an average pitch may be an average of values of a pitch between interconnections measured at any five points. In addition, an average insulation distance between the third wiring layers 123 may be less than an average insulation distance between the first wiring layer 121 and the fourth wiring layer 124 or an average interlayer insulation distance between a plurality of fourth wiring layers 124. The interlayer insulation distance may also be measured by photographing a cut cross-section of the printed circuit board using a scanning microscope, and the average interlayer insulation distance may be an average of values of an insulation distance between adjacent wiring layers measured at any five points. That is, the interconnection included in the third wiring layer 123 may be a high-density fine interconnection having a line/space (L/S) smaller than that of the interconnection included in the first wiring layer 121 and/or the interconnection included in the fourth wiring layer 124. As a non-limiting example, the line/space of the interconnection included in the third wiring layer 123 may be about 2/2 µm, but the present disclosure is not limited thereto. As the third wiring layer 220 has a high interconnection density, it may be effective when electronic components such as semiconductor chips are connected to each other. That is, the third wiring layer 123 may be used as a redistribution layer of a semiconductor chip.

The first wiring layer 121 and the fourth wiring layer 124 may have substantially the same interconnection density. Such a configuration does not mean that the first wiring layer 121 and the fourth wiring layer 124 needs to be designed to have the same interconnection density, and means that the first wiring layer 121 and the fourth wiring layer 124 have an interconnection density lower than that of the third wiring layer 123. The designs of the first wiring layer 121 and the fourth wiring layer 124 may be freely changed.

In general, a printed circuit board including a fine interconnection may be often subject to warpage caused by asymmetry of a board. However, the printed circuit board according to still another example may include a glass layer 110 having excellent stiffness. Thus, even when a fine interconnection is implemented only on one side of the board, the occurrence of warpage caused by asymmetry may be prevented.

In FIG. 5, the third wiring layer 123 is illustrated as being finer than the second wiring layer 122, but the present disclosure is not limited thereto, and the second wiring layer 122 and the third wiring layer 123 have substantially the same interconnection density. That is, without being limited to those illustrated in FIG. 5, the second wiring layer 122 may also include an interconnection finer than that of the first wiring layer 121 and/or that of the fourth wiring layer 124. In this case, a wiring layer having a fine interconnection may be directly disposed on the glass layer 110. That is, such a configuration means that a fine interconnection, such as a redistribution layer, may be directly disposed on the glass layer 110.

However, the present disclosure is not limited to those illustrated in FIG. 5, and the printed circuit board according to still another example may not include a core 200 in the same manner as the printed circuit board according to another example, but may be manufactured in strip units to be subject to a singulation process.

Descriptions of the printed circuit board according to still another example of FIG. 5, other than descriptions of an interconnection density and an insulation distance, may be applied in the same manner as descriptions of the printed circuit board according to an example and the printed circuit board according to another example, and thus repeated descriptions will be omitted.

### Method of Manufacturing Printed Circuit Board

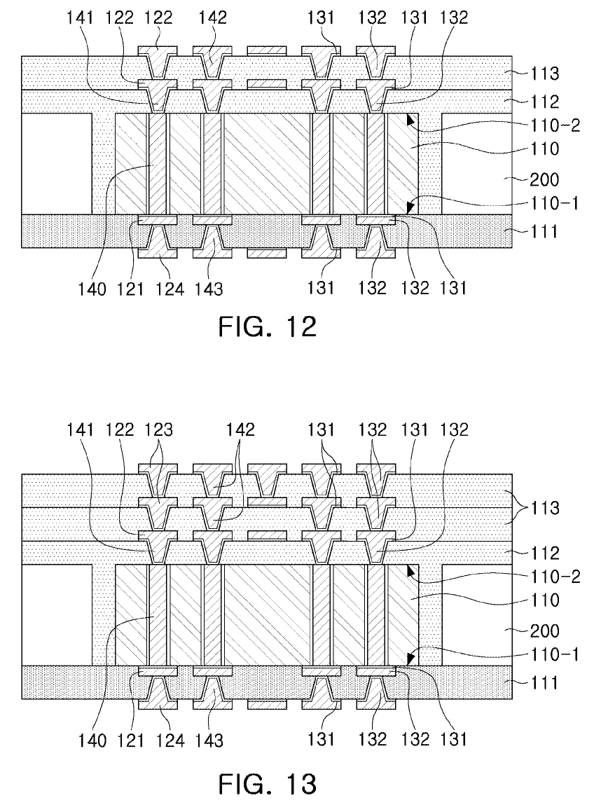

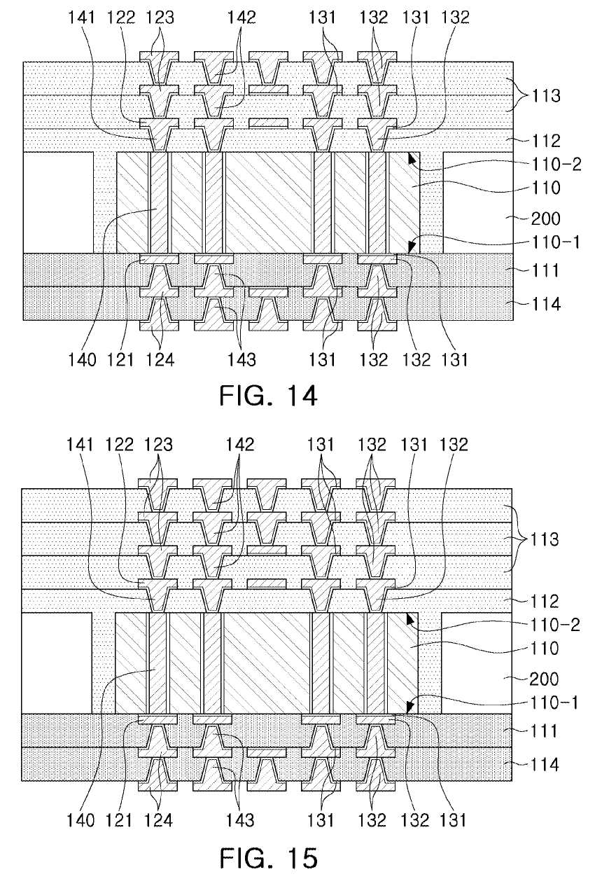

FIGS. 6, 7, 8, 9, 10, 11, 12, 13, 14, 15 and 16 are schematic cross-sectional views illustrating an example of a method of manufacturing a printed circuit board.

Referring to FIG. 6, a glass layer 110 may be disposed in a through-hole of a core 200, and the glass layer 110 may be fixed using an adhesive member 300. In this case, a surface of the glass layer 110, coupled to the adhesive member 300, may be illustrated as a first surface 110-1, and a surface opposing the first surface 110-1 may be illustrated as a second surface 110-2.

The core 200 may have features the same as those described in connection with the printed circuit board according to an example, but the present disclosure is not limited thereto, and may be a temporary component as a frame or jig as described above in connection with the printed circuit board according to another example. Any adhesive means that could be used by those skilled in the art may be used as the adhesive member 300 without limitation. For example, a known tape or the like may be used. The glass layer 110 may be attached to the through-hole of the core 200 through the adhesive member 300, such that the first surface 110-1 of the glass layer 110 and a lower surface of the core 200 may be substantially coplanar with each other.

A through-via 140 may be formed in the glass layer 110. An operation of forming the through-via 140 in the glass layer 110 may also be used without limitation as long as the operation is a method that could be used by those skilled in the art. After a through-hole is formed in the glass layer 110, the through-via 140 may be formed by forming a seed layer and forming a plating layer. The through-hole may be formed using various methods such as laser processing, mechanical processing, and chemical processing, and the seed layer may be formed using electroless plating (or chemical copper plating) or sputtering. The plating layer may be subjected to electrolytic plating (or electrolytic copper plating). Thereafter, the first surface 110-1 and the second surface 110-2 of the glass layer 110 may be subject to a planarization process to have a flat surface, as necessary.

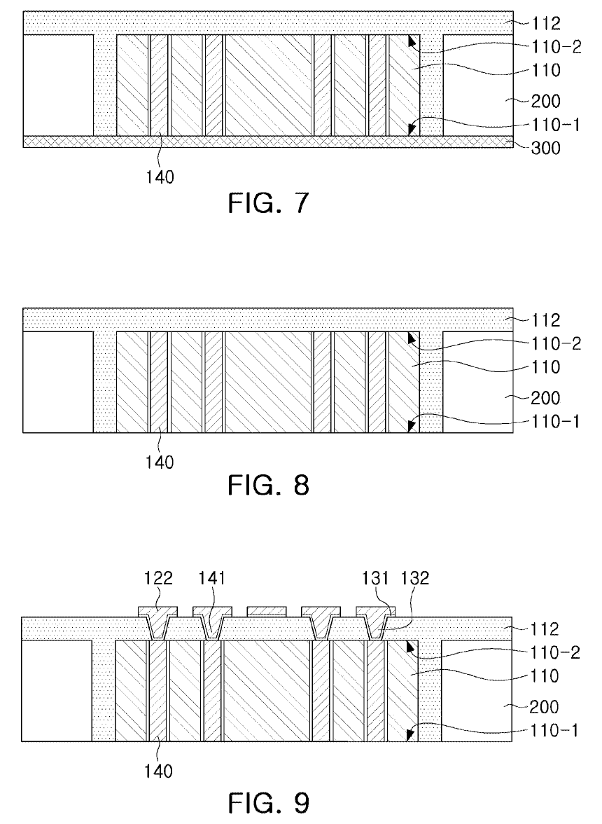

Referring to FIG. 7, a second insulating layer 112 may be disposed to bury the glass layer 110. The second insulating layer 112 may be disposed on the second surface 110-2 of the glass layer 110, and may be formed by stacking a semi-cured insulating layer and then curing the semi-cured insulating layer. The second insulating layer 112 may cover a side surface of the glass layer 110 to fill the through-hole of the core 200.

Referring to FIG. 8, the adhesive member 300 may be removed. Even when the adhesive member 300 is removed, the glass layer 110 may be fixed through the second insulating layer 112.

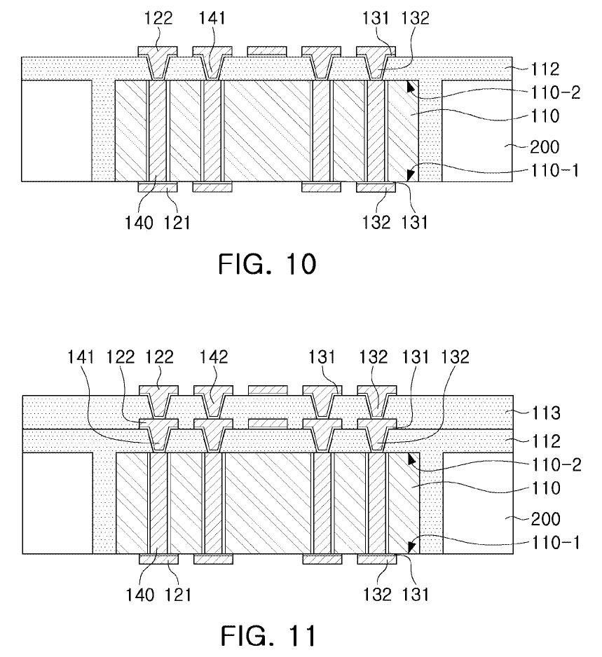

Referring to FIGS. 9 and 10, a connection via 141 and a second wiring layer 122 may be formed, and a first wiring layer 121 may be formed.

After a via hole penetrating the second insulating layer 112 is formed, the connection via 141 and the second wiring layer 122 may be formed by forming a first metal layer 131 and a second metal layer 132. An operation of forming the first wiring layer 121 may also be performed by forming the first metal layer 131 and the second metal layer 132. In this case, the first metal layer 131 of the connection via 141 may be in contact with an upper surface of the through-via 140, and may cover the upper surface of the through-via 140.

The first wiring layer 121 may be formed directly on the first surface 110-1 of the glass layer 110, and thus the first metal layer 131 of the first wiring layer 121 may be disposed to cover a lower surface of the through-via 140. That is, the first wiring layer 121 may be formed after the first surface 110-1 of the glass layer 110 is flattened, the first wiring layer 121 may be distinguished from the through-via 140, and the first metal layer 131, a seed layer of the wiring layer 121, may be disposed to cover the through-via 140. That is, after the adhesive member 300 is removed, the first wiring layer 121 may be formed on a surface from which the adhesive member 300 is removed.

Referring to FIGS. 9 and 10, it is illustrated that the first wiring layer 121 is formed after the second wiring layer 122 is formed, but the present disclosure is not limited thereto, and the first wiring layer 121 and the second wiring layer 122 may be formed simultaneously in a single process, or the second wiring layer 122 may be formed after the first wiring layer 121 is formed. That is, the order of forming the second wiring layer 122 and the first wiring layer 121 may be unlimited.

In the printed circuit board according to an example, the first wiring layer 121 may be formed after the glass layer 110 having the through-via 140 is buried by the second insulating layer 112, such that the first metal layer 131 of the first wiring layer 121 may be formed to be distinguished from the through-via 140. That is, the first metal layer 131 of the first wiring layer 121 may be disposed to be in contact with the through-via 140, and may be disposed on the first surface of the glass layer 110. On the basis of the same principle, the first metal layer 131 of the connection via 141 may also be distinguished from the through-via 140, and may have a similar arrangement.

Referring to FIGS. 11 to 15, a first insulating layer 111, a third insulating layer 113, and a fourth insulating layer 114 may be formed, and a third wiring layer 123 and a fourth wiring layer 124 may be formed. First, the third insulating layer 113 and the third wiring layer 123 may be formed on the second insulating layer 112. Thereafter, the first insulating layer 111 may be formed on the first surface 110-1 of the glass layer 110, and the fourth wiring layer 124 may be formed on the first insulating layer 111. Thereafter, the third insulating layer 113 and the third wiring layer 123, and the fourth insulating layer 114 and the fourth wiring layer 124 may be repeatedly stacked. A method of forming an insulating layer and a method of forming a via layer and a wiring layer may be performed using a known method in the method of manufacturing a printed circuit board.

In the drawings, it is illustrated that the third insulating layer 113 is first formed and then the first insulating layer 111 is formed, but the present disclosure is not limited thereto, and an order of stacking the insulating layers may vary. In addition, in the drawings, it is illustrated that an operation of forming an insulating layer and a wiring layer on one side and then forming an insulating layer and a wiring layer on the opposite side is repeatedly performed, but the present disclosure is not limited thereto. A process may be performed in a manner of forming an insulating layer on each of one side and the opposite side, and then forming a wiring layer on each insulating layer. That is, an operation of building up layers may be performed simultaneously in both directions. In addition, in the drawings, it is illustrated that layers are built up on each of one side and the opposite side by one layer, but the present disclosure is not limited thereto. Layers may be built up on one side, and then layers may be built up on the opposite side. The printed circuit board according to an example, including the glass layer 110, may be protected from warpage, and thus may not be limited in terms of a build-up order or build-up type.

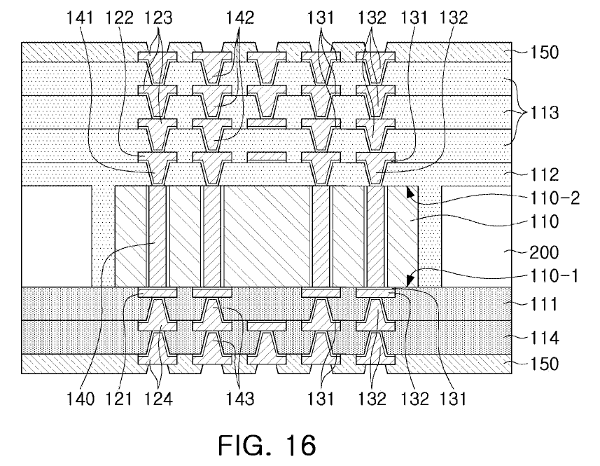

Referring to FIG. 16, a solder resist layer 150 may be formed on the third insulating layer 113 and/or the fourth insulating layer 114. To form the solder resist layer 150, known methods, such as lamination and coating, may be used.

The printed circuit board according to another example may be manufactured by removing the core 200 of the printed circuit board without being limited to those in the drawings, and the printed circuit board according to another example may be manufactured by changing an interconnection density and a build-up order during a build-up process. In addition, the present disclosure is not limited those illustrated in the drawings, and may further include a method of forming a component that could be used by those skilled in the art.

As used herein, the terms “cover,” “to cover,” and “covering” may include entirely covering as well as at least partially covering, and may include directly covering as well as indirectly covering. In addition, the terms “fill,” to fill,” and “filling” may include not only completely filling, but also approximately filling, for example, may include a case in which some voids, pores or the like are present.

As used herein, a process error or a positional deviation occurring in a manufacturing process, an error in measurement, and the like may be included. For example, “substantially perpendicular” may include not only “completely perpendicular,” but also “approximately perpendicular.” In addition, “substantially coplanar” may include not only “completely coplanar,” but also “approximately coplanar.”

As used herein, the same insulating material may mean not only the exact same insulating material, but also the same type of insulating material. Thus, compositions of insulating materials may be substantially the same, but specific composition ratios thereof may slightly vary.

As used herein, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

As used herein, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions, and the concepts of “upper” and “lower” may change at any time.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been shown and described above, it will be apparent to those skilled in the art that modifications and variations could be made without departing from the scope of the present disclosure as defined by the appended claims.

What is claimed is:

1. A printed circuit board comprising:
a glass layer having a first surface, a second surface opposing the first surface in a first direction, and a side surface connecting the first surface and the second surface;
a through-via penetrating at least a portion of the glass layer in the first direction;
an insulating body including a first insulating portion disposed on the first surface, a second insulating portion disposed on the second surface, and a third insulating portion disposed between the first and second insulating portions and covering the side surface;
a second wiring layer disposed on the second insulating portion;
a connection via penetrating the second insulating portion to connect the second wiring layer and the through-via to each other;
a plurality of third insulating layers disposed on the second insulating portion and covering at least a portion of the second wiring layer; and
a plurality of third wiring layers respectively disposed on or within the plurality of third insulating layers,
wherein the second wiring layer and the connection via include a first metal layer and a second metal layer disposed on the first metal layer, and
the first metal layer being in contact with the through-via and the second insulating portion.

2. The printed circuit board of claim 1, wherein the second wiring layer and the connection via are integrated with each other without an interlayer boundary.

3. The printed circuit board of claim 1, further comprising:
a fourth insulating layer disposed on the first insulating portion; and
a plurality of fourth wiring layers respectively disposed on or within the fourth insulating layer.

4. The printed circuit board of claim 3, wherein no wiring pattern is disposed on or within the third insulating layers and the fourth insulating layer in a region overlapping the third insulating portion in the first direction.

5. The printed circuit board of claim 3, further comprising:
a plurality of second via layers respectively penetrating at least a portion of each of the plurality of third insulating layers; and
a plurality of third via layers respectively penetrating at least a portion of the first insulating portion or at least a portion of the fourth insulating layer,
wherein the plurality of second via layers include first stacked vias disposed on the through-via in the first direction, and the plurality of third via layers include second stacked vias disposed on the through-via in the first direction.

6. The printed circuit board of claim 1, wherein the second insulating portion is in contact with at least a portion of the one surface of the through-via.

7. The printed circuit board of claim 1, wherein the third insulating portion is externally exposed.

8. The printed circuit board of claim 1, wherein the first insulating portion has an interlayer boundary with the third insulating portion, and
the second insulating portion is integrated with the third insulating portion without an interlayer boundary therebetween.

9. The printed circuit board of claim 8, wherein the first insulating portion includes an insulating material different from an insulating material of the third insulating portion.

10. The printed circuit board of claim 9, wherein the second insulating portion includes an insulating material substantially the same as an insulating material of the third insulating portion.

11. The printed circuit board of claim 10, wherein the first to third insulating portions respectively include a filler, and
each of the second and third insulating portions includes the filler finer than the filler included in the first insulating portion.

12. The printed circuit board of claim 1, further comprising:
a first wiring layer disposed on and in contact with the first surface of the glass layer;
one or more fourth insulating layers disposed on the first insulating portion, the one or more fourth insulating layers covering at least a portion of the first wiring layer; and
one or more fourth wiring layers respectively disposed on or within the fourth insulating layers.

13. The printed circuit board of claim 12, wherein the number of the third wiring layers is greater than the number of the fourth wiring layers, and
the number of the third insulating layers is greater than the number of the fourth insulating layers.

14. The printed circuit board of claim 12, wherein an average pitch of an interconnection included in the same third wiring layer among the third wiring layers is shorter than an average pitch of an interconnection included in the first wiring layer.

15. The printed circuit board of claim 12, wherein the third insulating layers include a material substantially the same as an insulating material of the second insulating portion, and
the fourth insulating layers include a material substantially the same as an insulating material of the first insulating portion.

16. The printed circuit board of claim 1, further comprising:
a core having a through-hole,
wherein the glass layer is disposed in the through-hole.

17. The printed circuit board of claim 16, wherein the core includes a copper clad laminate.
